(19) United States
(12) Patent Application Publication
(10) Pub. No.: US 2026/0100209 A1
(43) Pub. Date: Apr. 9, 2026

(54) Dummy Wordline Driver Circuitry and Methods

(71) Applicant: Arm Limited, Cambridge (GB)

(72) Inventors: Disha Singh, Bangalore (IN); Rajiv Kumar Sisodia, Bangalore (IN); Prashantkumar Jayantilal Vaghasia, Austin, TX (US)

(21) Appl. No.: 18/910,457

(22) Filed: Oct. 9, 2024

(51) Int. Cl. G11C 8/08; G11C 8/06; G11C 8/18

(52) U.S. Cl. CPC G11C 8/08; G11C 8/06; G11C 8/18

(57) ABSTRACT

A circuit to precharge a dummy wordline includes a first branch comprising first and second PMOS devices; and a second branch comprising a single PMOS device. Also, in response to a power supply transition, the second branch can be configured to precharge the dummy wordline through the single PMOS device. Also, a method to precharge a dummy wordline includes: precharging, by a first branch of a circuit, a dummy wordline, and in response to a power supply transition, precharging the dummy wordline through a single PMOS device of a second branch of the circuit.

### I. FIELD

The present disclosure is generally related to dummy wordline driver circuitry and methods.

### II. DESCRIPTION OF RELATED ART

Modern System-on-Chip (SoC) designs increasingly employ multiple voltage domains to optimize performance and power consumption. This strategy extends to memory subsystems, where supporting several dual rail domains has become crucial for achieving an optimal balance between speed and energy efficiency. The implementation of multiple voltage domains in memory systems, however, creates a significant design challenge: the need for level-shifters at both the memory periphery and core interface. Such level-shifters are essential components that facilitate signal translation between different voltage domains to ensure data integrity and reliable operation.

At the memory periphery, level-shifters interface with other SoC components operating at various voltages. At the core interface, they mediate between the memory array and its control circuitry. For both locations, level-shifters should: operate with minimal delay to maintain system timing, consume less power to preserve energy efficiency, occupy minimal area in increasingly dense chip designs, and handle dynamic voltage differentials present in SoC operations. The growing complexity of SoC architectures and the push for higher performance with lower power consumption have intensified the demands on these level-shifters. Current solutions often struggle to meet all requirements simultaneously, particularly in advanced process nodes.

There is, therefore, a pressing need for innovative level-shifting solutions that can effectively address the challenges posed by multi-domain memory systems in modern SoCs. Such solutions would not only enhance signal integrity and power efficiency but also provide the flexibility and scalability required for future chip designs. Moreover, current solutions typically lack effective mechanisms to accurately track and mimic the behavior of actual memory components across different voltage domains. This limitation leads to inconsistencies in timing and performance, particularly under varying operating conditions. Hence, there is also a pressing need in the art for innovative solutions that can address these challenges in multi-domain memory systems as well. Such solutions must effectively manage the complexities of cross-domain signal management, optimize power consumption, ensure consistent performance, and maintain reliability across diverse operating conditions.

### III. BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1 is a schematic diagram of an example circuit in accordance with various implementations described herein.

FIGS. 2A, 2B, and 2C are schematic diagrams used in conjunction with example circuits in accordance with various implementations described herein.

FIG. 3 is a waveform diagram corresponding to FIG. 1 in accordance with various implementations described herein.

FIG. 4 is a schematic diagram used in conjunction with example circuits in accordance with various implementations described herein.

FIG. 5A is a schematic diagram of an example circuit in accordance with various implementations described herein.

FIG. 5B is a schematic diagram used in conjunction with example circuits in accordance with various implementations described herein.

FIG. 5C is a waveform diagram corresponding to FIG. 5A in accordance with various implementations described herein.

FIG. 6 is an operational method in accordance with various implementations described herein.

FIG. 7 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### IV. DETAILED DESCRIPTION

Implementations of the present disclosure are described below with reference to the drawings. In the description, common features are designated by common reference numbers throughout the drawings.

In one implementation, the present disclosure describes a circuit to precharge a dummy wordline, which may include a first branch that includes first and second PMOS devices and a second branch including a single PMOS device. In response to a power supply transition, the second branch can be configured to precharge the dummy wordline through the single PMOS device. In certain examples, “precharge the dummy wordline” refers to setting the dummy wordline to a predetermined voltage level prior to an actual operation or evaluation phase of the circuit. Also, in certain examples, “power supply transition” refers to a level-shifting between two different voltage domains, such as peripheral and core operating voltages.

In another implementation, the disclosure describes a method to precharge a dummy wordline, which includes: 1) precharging, by a first branch of a circuit, a dummy wordline, and 2) in response to a power supply transition, precharging the dummy wordline through a single PMOS device of a second branch of the circuit.

Certain definitions have been provided herein for reference. The term VDDPE is peripheral operating voltage (e.g., peripheral voltage domain, supply voltage domain) provided from a supply voltage power rail that is used for main power supply to power at least peripheral circuitry of an integrated circuit. The term VDDCE is core operating voltage (e.g., a core voltage supply, core voltage domain) provided from a core voltage power rail and specifically used to power bitcell memory arrays. VDDPE and VDDCE can have different voltage levels to optimize for power consumption and performance. For instance, core components may require a lower voltage for efficiency and to reduce heat generation.

The term CLK refers to an external clock signal. NGTP is an internal clock signal for the inventive design created from CLK and has an opposite polarity to that of CLK (e.g., an inverted clock signal). NGTP_VDDPE refers to an inverted clock signal (NGTP) configured to a bitcell operating voltage/ supply operating voltage (e.g., an inverted clock signal configured to peripheral operating voltage/ supply operating voltage). In certain implementations, NGTP may be used interchangeably with NGPT_VDDPE. NGPT_VDDCE is a derived signal from NGTP that is used for level shifting to the core operating voltage (e.g., an inverted clock signal configured to a core operating voltage). GTP is a derived inverted signal generated by NGTP through a logic circuitry (e.g., such as an inverter) (e.g., a derivation of an inverted clock signal). In various implementations, GTP is a global timing pulse signal of the circuitry. GTP_DELAYED is a further derived inverted signal generated by NGPT through logic circuitry (e.g., one or more inverters). As such, GTP_DELAYED is a delayed derivation of an inverted clock signal. GTP_VDDCE is a derivation of an inverted clock signal configured to a core operating voltage.

Level-shifters, as defined herein, are circuits placed at the edges of memory blocks and within their core interfaces. They allow signals to move smoothly between areas of the chip operating at different voltages. Dummy wordlines (DWL) are special circuits that track and mimic the behavior of actual memory wordlines. They help ensure accurate timing and reliability, especially when the chip is running under various operating conditions.

Inventive aspects, as described herein, provide faster, smaller, wide-range, and programmable dummy wordline (DWL) circuit driver designs (e.g., used to track wordlines) for level-shifters and memories. These innovative features offer multiple advantages: they maintain timing efficiency in single-rail domains, enhance operational margins for supplementary voltage domains, and provide programmable flexibility to ensure robust performance in scenarios where peripheral voltage (VDDPE) is reduced. This adaptive approach optimizes circuit behavior across varying power configurations, balancing performance and reliability.

Such innovative aspects presented herein offer significant advancements in dummy wordline (DWL) management such as-:

1) Enhanced Precharging Mechanism: Certain example designs enable a two-stage DWL precharging process. Initially, the DWL is powered through the peripheral voltage supply (VDDPE), followed by a seamless transition to the core voltage supply (VDDCE). This approach allows the DWL to achieve a higher voltage level, aligning with the core operating voltage.

2) Independent Precharging Control: Unlike previous designs, this novel approach eliminates the dependency on feedback signals derived from the DWL itself for precharging. Hence, the inventive circuit designs and methods eliminate potential timing conflicts by not having any reliance on various feedback dependencies. Instead, innovative precharge processes can be orchestrated through various derivations of the external clock signal, such as inversions and delays. This independence enhances reliability and simplifies the control mechanism.

3) Optimized Circuit Design: An additional key feature of various inventive implementations is the prevention of direct paths between peripheral and core operating voltages. This optimization contributes to improved power efficiency and reduced risk of voltage conflicts. These innovative features collectively provide a more robust, efficient, and flexible approach to DWL management in multi-voltage domain scenarios. By leveraging external clock signals and implementing strategic voltage transitions, the design achieves superior control over DWL behavior while maintaining circuit integrity across different power domains.

In addition, the innovative schemes and techniques described herein offer enhanced versatility in power management. They not only can support traditional single power rail configurations and scenarios where the periphery voltage supply (VDDPE) is up to 250 mV lower than the core operating voltage (VDDCE), but also extend capabilities to accommodate instances where VDDPE exceeds VDDCE by up to 200 mV. For example, this expanded operational range is particularly beneficial for advanced 3nm and 2nm process technologies, providing greater flexibility in power domain design and optimization.

The innovative schemes and techniques presented herein offer distinct advantages across various example voltage level-shifting scenarios:

1) Equal Voltage Domains (VDDPE = VDDCE): In this scenario, where peripheral and core operating voltages are equivalent, the design introduces no stage delay, thereby preserving optimal power, performance, and area (PPA) metrics.

2) Elevated Peripheral Voltage (VDDPE > VDDCE): When the peripheral voltage exceeds the core operating voltage, the design maintains margin integrity. Both the dummy wordline (DWL) and the actual wordline operate at the core voltage (VDDCE), mitigating potential timing discrepancies.

3) Significantly Reduced Peripheral Voltage (VDDPE << VDDCE): This challenging scenario is addressed through novel circuitry that offers the option to skew a global timing pulse (GTP) across two circuit branches, effectively minimizing margin impact. Furthermore, an edge mode average (EMA) programmable delay feature can be incorporated, providing enhanced margin control.

These innovative aspects not only address various voltage configurations but also offer additional benefits. The circuitry's design, requiring fewer PMOS devices, results in a substantially reduced footprint. This compact architecture contributes to overall area efficiency without compromising functionality. By accommodating these diverse voltage scenarios, the proposed technology demonstrates significant versatility in managing level-shifting challenges across different power domain configurations.

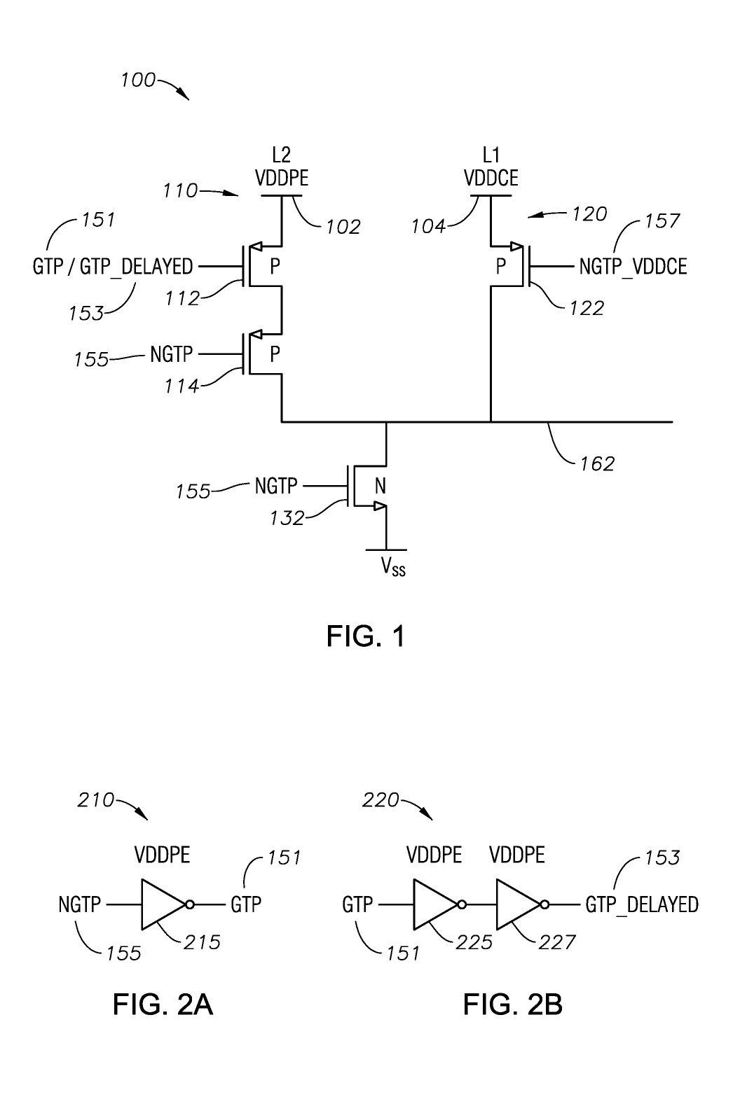

Referring to FIG. 1, a circuit 100 to precharge a dummy wordline (DWL) according to example implementations is shown. As illustrated, the circuit 100 (e.g., a DWL driver circuitry, DWL generator to track wordlines) may include a first circuit branch 110 (e.g., a first branch) and a second circuit branch 120 (e.g., a second leg). For instance, the first branch 110 includes first and second PMOS devices 112, 114 (i.e., first and second PMOS transistors), and the second branch 120 includes a single PMOS device 122. In certain implementations, in response to a power supply transition, the second branch 120 can be configured to precharge (e.g., drive a setting voltage) a dummy wordline (DWL) 162 circuit path coupled to the circuit 110 through (e.g., via, by way of) the single PMOS device 122.

In certain implementations, the first PMOS device 112 of the first branch 110 is configured to be activated upon receiving a derivation of the NGTP inverted clock signal (i.e., GTP signal 151) or a delayed derivation of the NGTP inverted clock signal (i.e., GTP_delayed 153). As described in greater detail in later paragraphs, the power supply transition (e.g., from peripheral voltage to core voltage) can be based upon such an activation of the first PMOS device 112 when the GTP 151 or GTP_delayed 153 is received at a gate of the first PMOS 112. Also, the second PMOS device 114 of the second branch 110 is configured to receive the inverted clock signal itself (e.g., NGTP 155). As described in greater detail in later paragraphs, upon activation of the second PMOS device, the circuit 100 is configured to precharge the DWL 162 through the first branch 110 prior to the power supply transition. In certain cases, during the power supply transition, the single PMOS device 122 of the second branch 120 is configured to receive an inverted clock signalconfigured to core operating voltage (i.e., NGTP_VDDCE 157).

As illustrated, in certain implementations, the first branch 110 includes a supply voltage power rail 102 and is configured to peripheral operating voltage (VDDPE). The supply voltage power rail 102 is coupled to the first and second PMOS transistors 112, 124 in series. In contrast, the second branch 120 includes a core voltage power rail 104 and is configured to core operating voltage (VDDCE). The core voltage power rail 104 is coupled to the single PMOS device 122 of the second branch 120. Also, an NMOS device 132 may be coupled to both the first and second branches 110, 120, where the NMOS device 132 is coupled to the second PMOS device 114 of the first circuit branch 110 as well as the single PMOS device 122 of the second circuit branch 120. As shown, the inverted clock signal, NGTP 155 may transmitted to NMOS device 132. According to certain implementations, in a return mode (e.g., RET mode), NGTP 155 and GTP 151 can be forced to different voltage levels, for example, NGTP to a “1” and GTP to a “0”. Hence, no direct current (DC) paths would be formed.

Advantageously, the example innovative circuit design (as shown in FIG. 1), offers a suite of significant advantages in managing voltage domains and dummy wordline (DWL) operation. Engineered to drive the DWL at core operating voltage (VDDCE), inventive approaches of the present disclosure effectively address challenges that arise when the peripheral voltage domain (VDDPE) exceeds the core voltage domain, providing a novel solution to previously intractable issues in multi-domain voltage scenarios. One key feature of this design is the decoupling of read and write margins from the voltage differential between VDDPE and VDDCE, representing a significant advancement over previous designs where such independence was not feasible. By tying DWL arrival to the core operating voltage level, the innovative circuit design achieves superior read and write margins compared to single voltage domain implementations, particularly in scenarios involving multiple voltage domains. Advantageously, the example design also intentionally allows for improving the margin by introducing delay to transition the voltage from the peripheral power rail 102 to the core power rail 104 in underdrive domains. Further enhancing its capabilities, the innovative circuit design incorporates an EMA controlled programmable delay option, adding a layer of flexibility to the circuit's timing characteristics and allowing for fine-tuning to meet specific performance requirements. Notably, the power supply transition mechanism operates independently of feedback signals derived from the DWL, enhancing the robustness and reliability of the power management system. Through these innovations, a balance of performance, flexibility, and power efficiency across various voltage domain scenarios can be achieved; thereby, addressing longstanding challenges in multi-domain circuit design.

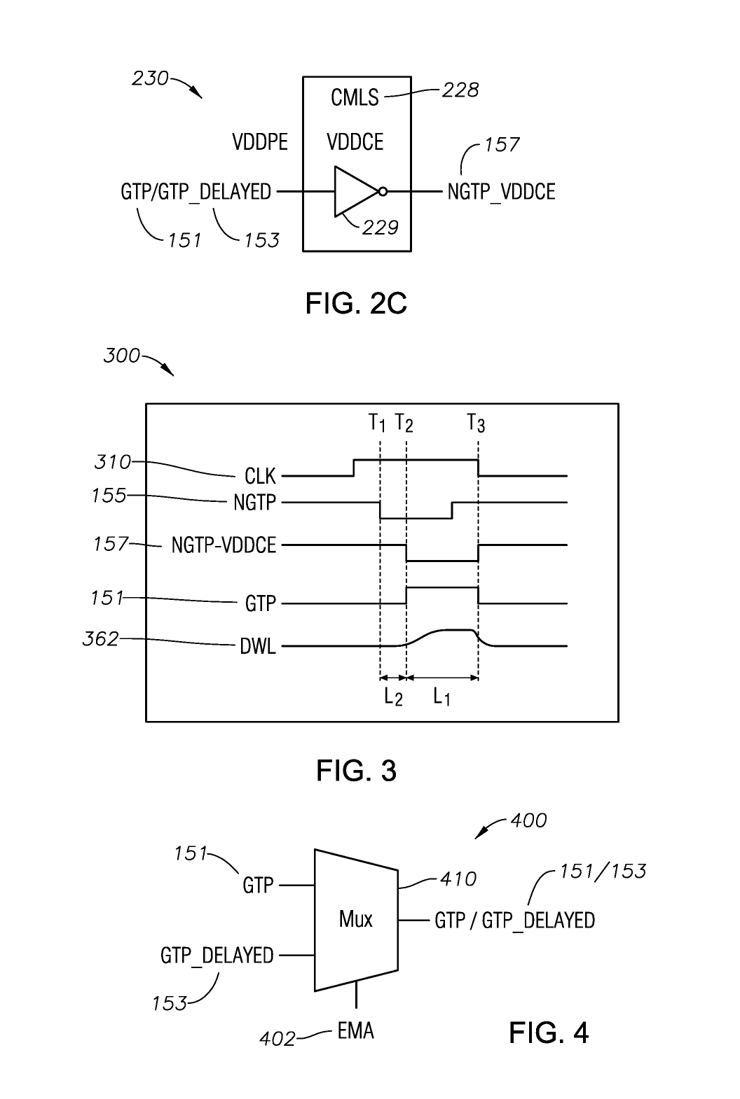

Referring to FIGS. 2A-2C, various different clock signal generation logics 210, 220, and 230 are shown according to example implementations. FIG. 2A illustrates the correlation between an inverted clock signal, NGTP 155, and GTP 151, a derived inverted signal that is generated by NGTP 155 (e.g. a derivation of an inverted clock signal). As depicted, GTP 151 can be generated by an inverter 215 configured for peripheral operating voltage (VDDPE). In one example implementation, the inverter 215 may be coupled to the circuit (100, 500), and can be configured to generate a derivation of an inverted clock signal (GTP 151) based on the inverted clock signal (NGTP 155). In other implementations, various other logic circuitry (e.g., buffers for delay requirements) to provide the same functional result can be used. FIG. 2B illustrates the correlation between GTP 151 and GTP_DELAYED 153, a further derived inverted signal generated by NGPT 155 (e.g., GTP_DELAYED 153 being a delayed derivation of an inverted clock signal). As depicted, GTP_DELAYED 153 can be generated by first and second inverters 225, 227, each configured for peripheral operating voltage (VDDPE). In one implementation, the first and second inverters 225, 227 may be coupled to the circuit (100, 500), and can be configured to generate a delayed derivation of an inverted clock signal (GTP_DELAYED 153) based on a derivation of the inverted clock signal (GTP 151). In other implementations, various other logic circuitry (e.g., buffers for delay requirements) to provide the same functional result can be used. FIG. 2C illustrates the correlation between GTP 151 or GTP_DELAYED 153 and NGTP_VDDCE 157, a derived signal from NGTP 155 that is used for level shifting to the core operating voltage (e.g., NGTP_VDDCE 157 is an inverted clock signal configured to a core operating voltage). As depicted, NGTP_VDDCE 157 can be generated by a common mode level shifter (CMLS) 228 incorporating an inverter 229 configured for core operating voltage (VDDCE) based on a derivation of the inverted clock signal (GTP 151) or a delayed derivation of the inverted clock signal (GTP_DELAYED 153). In one implementation, the CMLS 228 may be configured to transmit the inverted clock signal configured to the core operating voltage (NGPT_VDDCE 157)to the single PMOS device 122 of the second branch 120. In other implementations, various other logic circuitry to provide the same functional result can be used.

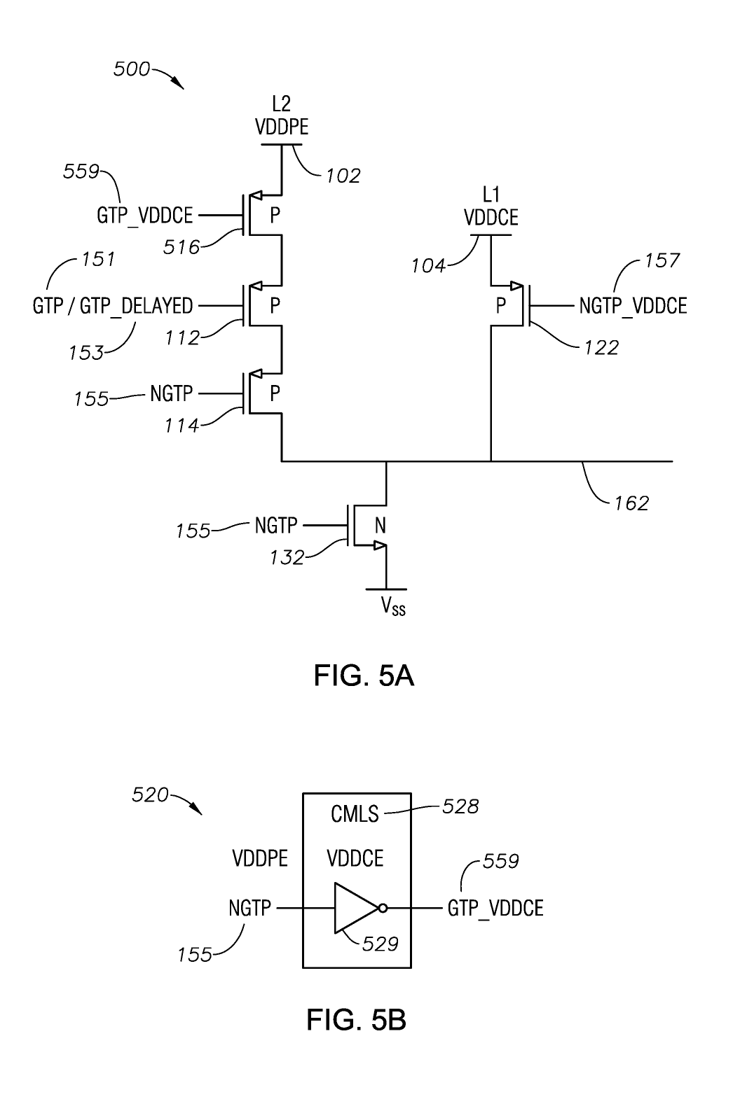

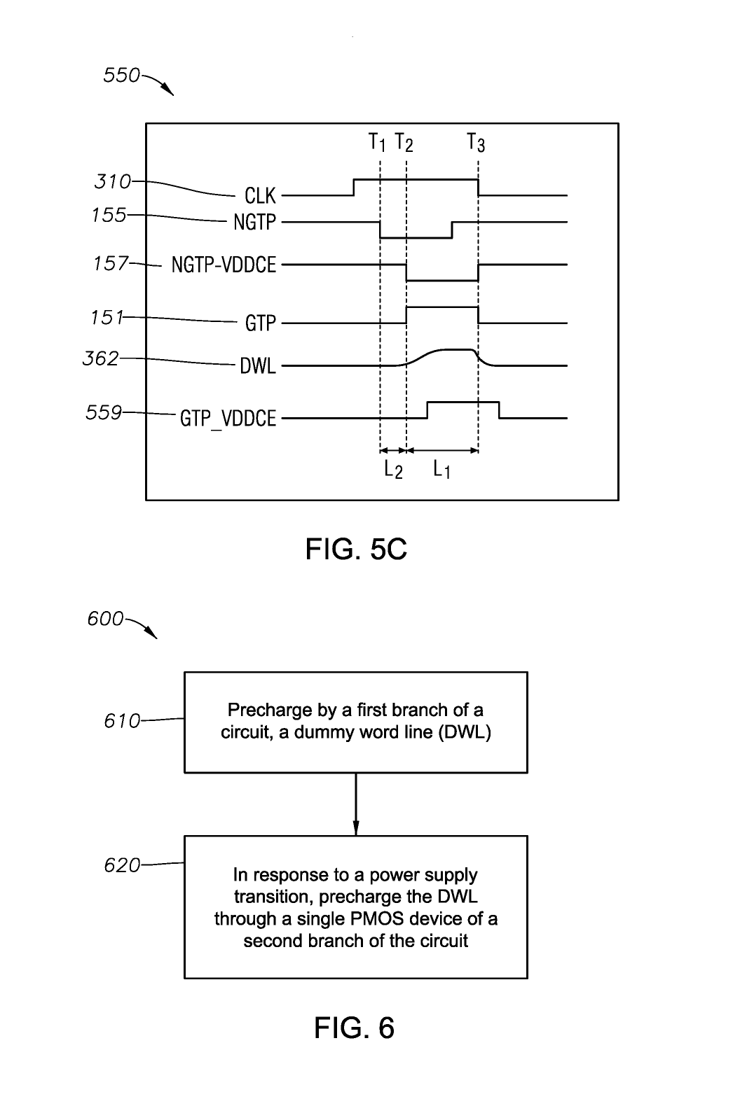

Referring to FIG. 3, an example timing diagram 300 is shown according to one example implementation. The timing diagram 300 corresponds to an example signal operations with reference to the inventive circuits 100, 500 of FIGS. 1 and 5, respectively. As illustrated, FIG. 3 depicts waveforms CLK 310, NGTP 155, NGTP_VDDCE 157, GTP 151, and DWL pulse 362. At time T1, for example, in response to a voltage level of NGTP 155 falling from high to low, the first branch 110 would commence precharging (e.g., driving a setting voltage) the dummy word line (DWL) 162 on the peripheral voltage (VDDPE) circuit path (L2). Next, at time T2, the voltage level of NGTP_VDDCE 152 falls from high to low. For instance, the duration (L2) between times T1 and T2 corresponds to the time interval whereby the first branch 110 is configured to precharge the DWL 162 (e.g., the DWL pulse 362 rises from during the L2 duration). Correspondingly, also at time T2, the voltage level of GTP 151 (or GTP_DELAYED 153 in other examples) would rise to high, whereupon the first branch 110 is “shut down” and the peripheral voltage (VDDPE) circuit path (L2) no longer precharges the DWL 162. In addition, at time T2, NGTP_VDDCE 157 would fall to a voltage low (e.g., at the arrival of NGTP_VDDCE 157 to the second branch 120), whereupon now, the second branch 120 at the core operating voltage (VDDCE) would be configured to precharge the DWL 162 on the core voltage (VDDCE) circuit path (L1). By doing so, advantageously, the DWL pulse 362 is first raised by the L2 branch, and then subsequently, rises to the core voltage level (VDDCE). Also, since the GTP 151 or GTP_DELAYED 153 is “turned off” (on the first branch 110), the DWL 162 would remain at the core voltage (VDDCE). As may be appreciated, this transition from the peripheral voltage (VDDPE) circuit path (L2) to the core voltage (VDDCE) circuit path (L1) is the power supply transition (e.g., level-shift) as described in paragraphs herein. Also, as shown, at time T3, GTP would fall (e.g., “turned on”), and precharging through the core voltage (VDDCE) circuit path (L1) may be turned off. Hence, for the duration L1 between times T2 and T3, precharging of the DWL 162 would occur via the second branch 120. In certain implementations, the delays of the NGTP_VDDCE 157 and GTP_DELAYED 153 can be made to be similar, and therefore would have the least impact during operations where peripheral voltage is greater than core voltage (i.e., VDDPE > VDDCE scenarios).

Referring to FIG. 4, an example delay generation circuit portion 400 is shown according to an example implementation. The circuit portion 400 illustrates an edge mode average (EMA) delay controller that can be added in for a GTP 151 path for underdrive (UD) domains (e.g., when VDDPE is significantly less than VDDCE). As shown, the circuit portion 400 includes a first logic 410 (e.g., multiplexer), whereupon the first logic 410 can be coupled to the circuit (100, 500), and can be configured to transmit a derivation of an inverted clock signal (GTP 151)or a delayed derivation of the inverted clock signal (GTP_DELAYED 152) to the circuit (100, 500) based on an edge mode average (EMA) pin selection (e.g., EMA pin either at a high level or a low level; a digital “1” or “0”). For example, in one operation, when peripheral operating voltage is greater than or equal to core operating voltage (VDDPE ≥ VDDCE), EMA=0 and GTP 151 would generate GTP/GTP_DELAYED 151/153 signal. Also, for example, in a second operation, when core operating voltage is greater than peripheral operating voltage (VDDCE > VDDPE), EMA=1 and GTP_DELAYED 153 generates GTP/GTP_DELAYED 151/153 signal. In other examples, an EMA delay controller option can be implemented with other logic circuitry.

Advantageously, utilizing such an implementation of FIG. 4 along with the NGTP_VDDCE 157 signal generation (as shown in FIG. 2C), GTP_DELAYED 152 can be employed to delay the core voltage (VDDCE) circuit path (L1) on the second branch 120. Hence, the DWL pulse 362 would rise with the peripheral voltage (VDDPE) for a prolonged duration (e.g., until the arrival of the NGTP_VDDCE 157 to the second branch 120). Moreover, by doing so, the DWL pulse 362 slope can be degraded and further margin can be provided for the underdrive (UD) domain, if desired. By averaging multiple signal edges, the EMA delay controller option provides superior timing precision and stability, crucial for high-speed circuits with tight margins. Their adaptive nature allows dynamic adjustment to varying voltage differentials and operating conditions, enhancing signal integrity across domains. The EMA controller can contribute to power efficiency through optimized timing and support higher operating frequencies. Also, its programmability enables post-production fine-tuning, while its reduced sensitivity to process variations improves overall reliability.

Referring to FIGS. 5A-5C, a lesser active mode current DWL circuitry and operation is described according to example implementations. In certain scenarios with reference to the DWL driver circuit 100, when peripheral operating voltage is significantly less than core operating voltage (VDDPE << VDDCE), and the DWL 162 circuit path is configured to core operating voltage (VDDCE), a node (not shown) between the first and second PMOS devices 112, 114 would be at core operating voltage (VDDCE). This would be the case because each of the gates of the first and second PMOS devices 112 and 114 would be controlled by the much lesser peripheral voltage (VDDPE) when GTP 151/ GTP_delayed 153 is “off” (e.g., when GTP 151 rises). Hence, during an operation, when the DWL pulse 362 is risen to the core operating volage (VDDCE), by turning “on” the core operating voltage (VDDCE) circuit path (L1), the first PMOS device 112 would have its source connection at the core operating voltage (VDDCE). Since the core operating volage (VDDCE) is greater than peripheral operating voltage (VDDPE), the first PMOS device 112 would at least partially “turn on” due to there being a negative gate-to-source voltage. Also, the unintended turning on of the first PMOS device 112 would additionally cause at least some leakage current. Thus, to avoid this unintended scenario where a direct path may be formed between peripheral and core voltages that results in higher current for the DWL 362 pulse, the example DWL driver circuit 500 (e.g., Lesser Active Mode) may be implemented.

FIG. 5A illustrates an example circuit 500 according to example implementations. As illustrated, similar to FIG. 1, the circuit 500 (e.g. DWL driver circuit, DWL generator to track wordlines) may include a first circuit branch 110 (e.g., a first branch) and a second circuit branch 120 (e.g., a second branch). For instance, the first branch 110 includes first and second PMOS devices 112, 114 (i.e., first and second PMOS transistors) as well as a third PMOS device 516 (i.e., a third PMOS transistor), and the second branch 120 includes a single PMOS device 122. In certain implementations, in response to a power supply transition, the second branch 120 can be configured to precharge (e.g., drive a setting voltage) a dummy wordline (DWL) 162 circuit path coupled to the circuit 110 through (e.g., via, by way of) the single PMOS device 122.

In contrast to the circuit 100 of FIG. 1, the circuit 500 further includes the third PMOS device 516 that is coupled in series to the first and second PMOS devices 112, 114, whereupon the third PMOS device 516 is configured to receive a derivation of an inverted clock signal configured to core operating voltage (GTP_VDDCE 559). In one example operation, the third PMOS device 516 is configured to be deactivated when peripheral supply voltage (VDDPE) is greater than core voltage (VDDCE) on the first branch 110 itself, thereby ensuring that no direct path would be formed between peripheral and core voltages. Advantageously, by including the third PMOS device 516, the circuit 500 can safeguard operation since regardless of whether peripheral voltage (VDDPE) or core voltage (VDDCE) is higher, at least one of the PMOS devices on the first branch 110 would be “turned on”, and thus allow the first branch 110 to be “cut off” and block a direct path between the peripheral and core voltages. Thus, ultimately, the circuit 500 may enhance energy efficiency.

Similar to the circuit 100 shown in FIG. 1, in certain implementations, for the circuit 500, the first branch 110 includes a supply voltage power rail 102 and is configured to peripheral operating voltage (VDDPE). The supply voltage power rail 102 is coupled to the first and second PMOS transistors 112, 124 in series. In contrast, the second branch 120 includes a core voltage power rail 104 and is configured to core operating voltage (VDDCE). The core voltage power rail 104 is coupled to the single PMOS device 122 of the second branch 120. Also, an NMOS device 132 may be coupled to both the first and second branches 110, 120, where the NMOS device 132 is coupled to the second PMOS device 114 of the first circuit branch 110 as well as the single PMOS device 122 of the second circuit branch 120. As shown, the inverted clock signal, NGTP 155 may transmitted to NMOS device 132. According to certain implementations, in a return mode (e.g., RET mode), NGTP 155 and GTP 151 can be forced to different voltage levels, for example, NGTP to a “1” and GTP to a “0”. Hence, no direct current (DC) paths would be formed.

Similar to the circuit 100 illustrated in FIG. 1, the circuit 500 in FIG. 5A introduces innovative approaches to voltage domain management and dummy wordline (DWL) control. Such innovative approaches work well where the peripheral voltage (VDDPE) is higher than the core voltage (VDDCE), a situation that previously posed significant challenges in multi-domain configurations. One key aspect includes the circuit's capacity to drive the DWL using VDDCE, which effectively decouples read and write margins from the VDDPE-VDDCE voltage difference. This decoupling marks a substantial improvement over earlier designs, where such voltage independence was unattainable. By linking DWL timing to VDDCE, such innovative approaches achieve enhanced read and write margins, outperforming single-domain setups, especially in complex multi-voltage environments. Such innovative approaches also incorporate a strategic approach to underdrive domains, allowing for controlled margin reduction in less critical areas operating at lower voltages, thus optimizing power consumption. Additionally, the inclusion of an Edge Mode Average (EMA) controlled programmable delay feature offers precise timing adjustments, enabling fine-tuned performance customization. Another key aspect of such innovative approaches lies in the power supply transition mechanism, which functions autonomously from DWL-derived feedback signals, significantly boosting the power management system's reliability. This suite of innovations results in a circuit design that capably balances performance, adaptability, and energy efficiency across diverse voltage scenarios, effectively addressing persistent challenges in multi-domain circuit architecture.

FIG. 5B illustrates an example clock signal generation logic 510 is shown according to an example implementation. FIG. 5B illustrates the correlation between an inverted clock signal, NGTP 155, and GTP_VDDCE 559, a derived inverted signal configured to core operating voltage (VDDCE) that is generated by NGTP 155 (e.g. a derivation of an inverted clock signal configured to core operating voltage (VDDCE). As depicted, NGTP_VDDCE 157 can be generated by a common mode level shifter (CMLS) 528 incorporating an inverter 529 configured for core operating voltage (VDDCE) based on a derivation of the inverted clock signal (GTP 151) or a delayed derivation of the inverted clock signal (GTP_DELAYED 153). In one implementation, the CMLS 528 may be configured to transmit the inverted clock signal configured to the core operating voltage (NGPT_VDDCE 157)to the single PMOS device 122 of the second branch 120. In other implementations, various other logic circuitry to provide the same functional result can be used.

FIG. 5C illustrates an example timing diagram 550 according to one example implementation. As illustrated, the timing diagram 550 corresponds to the example signal operations with reference to the inventive circuit 100 with one addition waveform, the waveform GTP_VDDCE 559. As illustrated, FIG. 5C depicts waveforms CLK 310, NGTP 155, NGTP_VDDCE 157, GTP 151, DWL pulse 362, and GTP_VDDCE 559. Similar to FIG. 3, at time T1, for example, in response to a voltage level of NGTP 155 falling from high to low, the first branch 110 may commence precharging (e.g., driving a setting voltage) the dummy word line (DWL) 162 on the peripheral voltage (VDDPE) circuit path (L2). Next, at time T2, the voltage level of NGTP_VDDCE 152 falls from high to low. For instance, the duration L2 between times T1 and T2 corresponds to a time interval that the first branch 110 would be configured to precharge the DWL 162 (e.g., the DWL pulse 362 rises from during the L2 duration). Correspondingly, also at time T2, the voltage level of GTP 151 (or GTP_DELAYED 153 in other examples) would rise to a high voltage value, whereupon the first branch 110 is “shut down” and the peripheral voltage (VDDPE) circuit path (L2) no longer precharges the DWL 162. In addition, at time T2, NGTP_VDDCE 157 would fall to a voltage low (e.g., at the arrival of NGTP_VDDCE 157 to the second branch 120), whereupon now, the second branch 120 at the core operating voltage (VDDCE) would be configured to precharge the DWL 162 on the core voltage (VDDCE) circuit path (L1). By doing so, advantageously, the DWL pulse 362 is first raised to the peripheral voltage level (VDDPE), and then subsequently, raised higher to the core operating voltage level (VDDCE) (e.g., at the “full rail”). Also, since the GTP 151 or GTP_DELAYED 153 is “turned off” (on the first branch 110), the DWL 162 would remain at the core voltage (VDDCE). As may be appreciated, this transition from the peripheral voltage (VDDPE) circuit path (L2) to the core voltage (VDDCE) circuit path (L1) is the power supply transition (e.g., level-shift) as described in paragraphs herein.

Subsequent to time T2, when the DWL pulse 362 reaches to the core operating voltage level (VDDCE), GTP_VDDCE can be programmed to be raised to a voltage high to ensure that the first PMOS device 112 would not be partially “turned on” and cause leakage current. Advantageously, the unintended consequence where a direct path is formed between peripheral and core voltages resulting in a higher current for the DWL 362 pulse can be prevented. As shown as well, at time T3, GTP may fall (e.g., “turned on”) and precharging through the core voltage (VDDCE) circuit path (L1) may be turned off. Hence, for the duration L1 between times T2 and T3, precharging of the DWL 162 would occur via the second branch 120. Advantageously, as well, subsequent to time T3, only after a delay whereupon the DWL pulse 362 has commenced falling, would GTP_VDDCE 559 be programmed to fall, thereby ensuring reliable circuit operation without such unintended consequences. In certain implementations, the delays of the NGTP_VDDCE 157 and GTP_DELAYED 153 can be made to be similar, and therefore would have the least impact during operations where peripheral voltage is greater than core voltage (i.e., VDDPE > VDDCE scenarios).

Referring to FIG. 6, a flowchart of an example operational method 600 (i.e., procedure) is shown. Advantageously, in various implementations, the method 600 provides the capability to precharge a dummy wordline via disabling a peripheral operating voltage (VDDPE)-coupled branch and transitioning (e.g., level-shifting) to a core operating voltage (VDDCE)-coupled branch. The method 600 may be implemented with reference to circuit implementations as shown in FIGS. 1-5C and 7.

At block 610, the example method 600 includes: precharging, by a first branch of a circuit, a dummy word line (DWL). For instance, as described with reference to FIGS. 1-5C and 7, in response to an inverted clock signal (e.g., NGTP 155) configured to peripheral operating voltage falling, a dummy wordline (DWL) 162 can be precharged (e.g., a setting voltage can be driven) by a first branch 110 of a DWL driver circuit (100, 500).

At block 620, the example method 600 includes: generating, in response to a power supply transition, precharging the DWL through a single PMOS device of a second branch of the DWL circuit. For instance, as described with reference to FIGS. 1-5C and 7, in response to a (logic-based) power supply transition (e.g., level-shift), the DWL 162 can be precharged through a single PMOS device 122 of a second branch 122 of the DWL driver circuit (100, 500).

In certain implementations, the power supply transition (e.g., level-shifting) occurs independent from one or more feedback signals based on the DWL. In some cases, the power supply transition is based on an activation of the first PMOS device 112, where the first PMOS device 112 is configured for activation upon receiving a derivation of an inverted clock signal (GTP 151) or a delayed derivation of the inverted clock signal (GTP_delayed 153). In certain instances, the power supply transition corresponds to a transition delay (i.e., level-shift delay), where the transition delay corresponds to a difference in duration (of arrivals to the circuit 100, 500) between an inverted clock signal (e.g., NGTP 155) configured to peripheral operating voltage (VDDPE) and an inverted clock signal configured to core operating voltage (e.g., NGTP_ VDDCE 157).

In some examples, precharging the DWL 162 by the first branch 110 includes: 1) in response to the second PMOS device 114 of the first branch 110 receiving an inverted clock signal (NGTP 155), activating the second PMOS device 114 of the first branch 110; and 2) upon the activation of the second PMOS device 114 of the first branch 110, precharging the DWL 162 through the first branch 110 prior to the power supply transition. In certain cases, precharging the DWL 162 by the single PMOS device 122 of the second branch 120 includes: 1) in response to the single PMOS device 122 receiving an inverted clock signal configured to core operating voltage (NGTP_VDDCE 157), activating the single PMOS device 122 of the second branch 120; and 2) upon the activation of the single PMOS device 122 of the second branch 120, precharging the DWL 162 through the second branch 120 after the power supply transition.

In some instances, the method 600 includes: receiving, by a third PMOS device 516 of the first branch 110, a derivation of an inverted clock signal configured to core operating voltage (GTP_VDDCE 559), where the third PMOS device 516 is configured to be deactivated when peripheral supply voltage (VDDPE) is greater than core voltage (VDDPE) on the first branch 110 (e.g., ensuring that there is no direct path between the peripheral voltage and core voltage).

Also, according to other aspects of the operational methods, an output may be generated based on the operational dispositions. For example, with reference to various implementations as described in FIGS. 1-5C, an output such as a DWL driver circuit design, a level-shifter and/or memory architecture, or a multi-threshold offering for memory compilers may be generated. In some implementations, the electronic design automation (EDA) tool 724 (e.g., incorporating a circuit design tool) may allow users to input certain values, and generate circuit designs incorporating the inventive DWL driver circuitry designs. Such a tool 724 may be focused on the creation, analysis, and verification of electronic circuits.

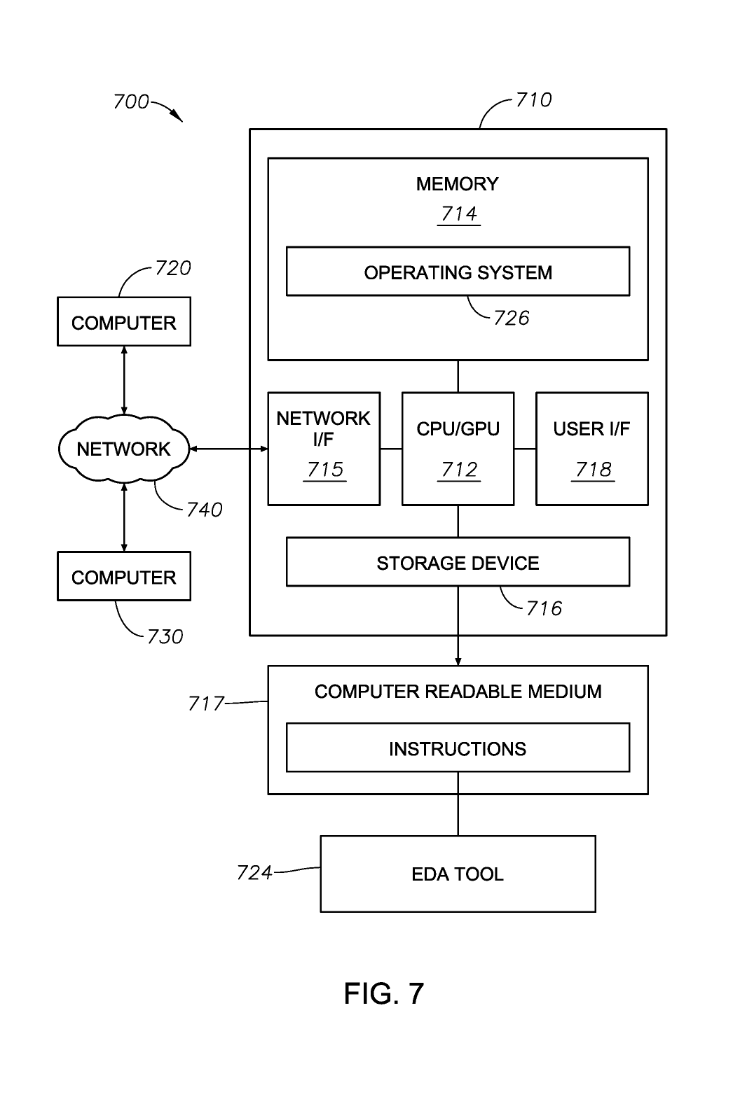

FIG. 7 illustrates example hardware components in the computer system 700 that may be used to facilitate and generate the inventive DWL driver circuit design/memory architecture output. In certain implementations, the example computer system 700 (e.g., networked computer system and/or server) may include EDA tool 724 and execute software based on the procedure as described with reference to the method 600 in FIG. 6.

For instance, the EDA tool 724 can generate the inventive DWL driver circuit designs, as described herein, through a systematic process combining user input and automated optimization. Initially, the tool would take in design specifications, including voltage domains, timing requirements, and process technology parameters. The EDA tool 724 can access a library of pre-designed circuit elements and apply rule-based algorithms to create an initial schematic. The EDA tool 724 can perform multiple iterations of simulation and analysis, adjusting transistor sizes, layout, and timing to meet performance criteria. Such a tool 724 can also incorporate level shifters and delay elements as needed, optimizing for power, area, and speed. The EDA tool 724 would also conduct design rule checks and verify the circuit's functionality across various operating conditions. Finally, the EDA tool 724 can generate the physical layout, considering factors like signal integrity and manufacturability. Throughout this process, the EDA tool 724 can provide the designer with options for manual intervention and fine-tuning, ensuring the final DWL driver design meets all specified requirements while adhering to best practices in circuit design.

Using the procedure 600, the EDA tool 724 may provide generated computer-aided physical layout designs for level-shifting and/or memory architecture. The procedure 600 may be stored as program code as instructions 717 in the computer readable medium of the storage device 716 (or alternatively, in memory 714) that may be executed by the computer 510, or networked computers 720, 730, other networked electronic devices (not shown) or a combination thereof. In certain implementations, each of the computers 710, 720, 730 may be any type of computer, computer system, or other programmable electronic device. Further, each of the computers 710, 720, 730 may be implemented using one or more networked computers, e.g., in a cluster or other distributed computing system.

In certain implementations, the computer system 700 may be used with semiconductor integrated circuit (IC) designs that contain all standard cells, all blocks or a mixture of standard cells and blocks. In a particular example implementation, the computer system 700 may include in its database structures: a collection of cell libraries, one or more technology files, a plurality of cell library format files, a set of top design format files, one or more Open Artwork System Interchange Standard (OASIS/ OASIS.MASK) files, and/or at least one EDIF file. The database of the computer system 700 may be stored in one or more of memory 714 or storage devices 716 of computer 710 or in networked computers 720, 730.

In one implementation, the computer system 700 includes a central processing unit (CPU) 712 having at least one hardware-based processor coupled to a memory 714. The memory 714 may represent random access memory (RAM) devices of main storage of the computer 710, supplemental levels of memory (e.g., cache memories, non-volatile or backup memories (e.g., programmable or flash memories)), read-only memories, or combinations thereof. In addition to the memory 714, the computer system 700 may include other memory located elsewhere in the computer 710, such as cache memory in the CPU 712, as well as any storage capacity used as a virtual memory (e.g., as stored on a storage device 716 or on another computer coupled to the computer 710).

The computer 710 may further be configured to communicate information externally. To interface with a user or operator (e.g., a circuit design engineer), the computer 710 may include a user interface (I/F) 718 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 710 may include a network interface (I/F) 715 which may be coupled to one or more networks 740 (e.g., a wireless network) to enable communication of information with other computers and electronic devices. The computer 760 may include analog and/or digital interfaces between the CPU 712 and each of the components 714, 715, 716, and 718. Further, other non-limiting hardware environments may be used within the context of example implementations.

The computer 710 may operate under the control of an operating system 726 and may execute or otherwise rely upon various computer software applications, components, programs, objects, modules, data structures, etc. (such as the programs associated with the procedure 600 and related software). The operating system 728 may be stored in the memory 714. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 726 in the example of FIG. 7 is shown in the memory 714, but components of the aforementioned software may also, or in addition, be stored at non-volatile memory (e.g., on storage device 716 (data storage) and/or the non-volatile memory (not shown). Moreover, various applications, components, programs, objects, modules, etc. may also execute on one or more processors in another computer coupled to the computer 710 via the network 740 (e.g., in a distributed or client-server computing environment) where the processing to implement the functions of a computer program may be allocated to multiple computers 720, 730 over the network 740. In example implementations, circuit diagrams have been provided in FIGS. 1-5C, whose redundant description has not been duplicated in the related description of analogous circuit diagrams. It is expressly incorporated that the same diagrams with identical symbols and/or reference numerals are included in each of embodiments based on its corresponding figure(s).

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user’s computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry, field-programmable gate arrays (FPGA), or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, such that the instructions, which execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit comprising:
a first branch comprising first and second PMOS devices; and
a second branch comprising a single PMOS device, wherein:
in response to a power supply transition, the second branch is configured to precharge a dummy wordline (DWL) through the single PMOS device.

2. The circuit of claim 1, wherein
the power supply transition is based on an activation of the first PMOS device, and
the first PMOS device is configured for activation upon receiving a derivation of an inverted clock signal or a delayed derivation of the inverted clock signal.

3. The circuit of claim 1, wherein during the power supply transition, the single PMOS device of the second branch is configured to receive an inverted clock signalconfigured to core operating voltage.

4. The circuit of claim 1, wherein the power supply transition occurs independent from one or more feedback signals based on the DWL.

5. The circuit of claim 1, wherein:
the first branch comprises a supply voltage power rail and is configured to peripheral operating voltage, and the supply voltage power rail is coupled to the first and second PMOS devices in series, and wherein:
the second branch comprises a core voltage power rail and is configured to core operating voltage, and the core voltage power rail is coupled to the single PMOS device of the second branch.

6. The circuit of claim 1, wherein:
the second PMOS device of the first branch is configured for activation upon receiving an inverted clock signal, and
upon activation of the second PMOS device, the circuit is configured to precharge the DWL through the first branch prior to the power supply transition.

7. The circuit of claim 1, further comprising:
an NMOS device coupled to the first and second branches, wherein:
the NMOS is coupled to the second PMOS device of the first circuit branch, and
the NMOS is coupled to the single PMOS device of the second circuit branch.

8. The circuit of claim 1, further comprising:
a common mode level shifter (CMLS) coupled to the circuit, wherein:
the CMLS is configured to generate an inverted clock signal configured to core operating voltage based on a derivation of the inverted clock signal or a delayed derivation of the inverted clock signal;
the CMLS is configured to transmit the inverted clock signal configured to the core operating voltage to the single PMOS device of the second branch.

9. The circuit of claim 1, further comprising:
an inverter, wherein:
the inverter is coupled to the circuit; and
the inverter is configured to generate a derivation of an inverted clock signal based on the inverted clock signal.

10. The circuit of claim 1, further comprising:
first and second inverters, wherein:
the first and second inverters are coupled to the circuit; and
the first and second inverters are configured to generate a delayed derivation of an inverted clock signal based on a derivation of the inverted clock signal.

11. The circuit of claim 1, further comprising:
a delay generation circuit, wherein:
the delay generation circuit is coupled to the circuit; and
the delay generation circuit is configured to transmit a derivation of an inverted clock signal or a delayed derivation of the inverted clock signal to the circuit based on an edge mode average (EMA) selection.

12. The circuit of claim 11, wherein a transmission of the delayed derivation of the inverted clock signal, by the delay generation circuit, is configured to delay the activation of the single PMOS device of the second branch.

13. The circuit of claim 1, wherein the first branch comprises:
a third PMOS device, wherein:
the first and second devices of the first branch are configured to peripheral operating voltage,
the third PMOS device is coupled in series with the first and second PMOS devices,
the third PMOS device is configured to receive a derivation of an inverted clock signal configured to core operating voltage, and
the third PMOS device is configured to be deactivated when the peripheral operating voltage is greater than the core operating voltage on the first branch.

14. A method comprising:
precharging, by a first branch of a circuit, a dummy wordline (DWL); and
in response to a power supply transition, precharging the DWL through a single PMOS device of a second branch of the circuit.

15. The method of claim 14, wherein the power supply transition occurs independent from one or more feedback signals based on the DWL.

16. The method of claim 14, wherein:
the power supply transition is based on an activation of a first PMOS device, and
the first PMOS device is configured for activation upon receiving a derivation of an inverted clock signal or a delayed derivation of the inverted clock signal.

17. The method of claim 14, wherein:
the power supply transition corresponds to a transition delay, and
the transition delay corresponds to a difference in duration between an inverted clock signal configured to peripheral operating voltage and an inverted clock signal configured to core operating voltage.

18. The method of claim 14, wherein precharging the DWL by the first branch comprises:
in response to a second PMOS device of the first branch receiving an inverted clock signal, activating the second PMOS device of the first branch; and
upon the activation of the second PMOS device of the first branch, precharging the DWL through the first branch prior to the power supply transition.

19. The method of claim 14, wherein precharging the DWL by the single PMOS device of the second branch comprises:
in response to the single PMOS device receiving an inverted clock signal configured to core operating voltage, activating the single PMOS device of the second branch; and
upon the activation of the single PMOS device of the second branch, precharging the DWL through the second branch after the power supply transition.

20. The method of claim 14, further comprising:
receiving, by a third PMOS device of the first branch, a derivation of an inverted clock signal configured to core operating voltage, wherein:
the third PMOS device is configured to be deactivated when peripheral operating voltage is greater than the core operating voltage on the first branch.
